(19) United States
(12) Patent Application Publication
(10) Pub. No.: US 2011/0241129 A1
(43) Pub. Date: Oct. 6, 2011

(54) TRANSISTOR, SEMICONDUCTOR DEVICE AND TRANSISTOR FABRICATION PROCESS

(75) Inventor: Michihiro Ebe, Miyagi (JP)

(73) Assignee: OKI SEMICONDUCTOR CO., LTD., TOKYO (JP)

(21) Appl. No.: 13/072,914

(22) Filed: Mar. 28, 2011

(30) Foreign Application Priority Data
Mar. 30, 2010 (JP) 2010-079465

(51) Int. Cl. H01L 29/78; H01L 21/336

(52) U.S. Cl. 257/408; 438/302; 257/E29.267; 257/E21.435

(57) ABSTRACT

The present invention provides a transistor, a semiconductor device and a transistor fabrication process that thoroughly ameliorate electric fields in a transistor element. Namely, the transistor includes a semiconductor substrate, incline portions, a gate electrode, side walls, and a source and a drain. The semiconductor substrate includes a protrusion portion at a surface thereof. The incline portions constitute side surface portions of the protrusion portion and are inclined from the bottom to the top of the protrusion portion. The gate electrode is formed on the top of the protrusion portion, with a gate insulation film interposed therebelow. The side walls are formed on the top of the protrusion portion at two side surfaces of the gate electrode and the gate insulation film. The source and the drain each include a low density region and a high-density region.

### CROSS-REFERENCE TO RELATED APPLICATION

This application claims priority under 35 USC 119 from Japanese Patent Application No. 2010-079465, filed on Mar. 30, 2010, the disclosure of which is incorporated by reference herein.

### BACKGROUND OF THE INVENTION

1. Field of the Invention

The present invention relates to a transistor, a semiconductor device and a transistor fabrication process.

2. Description of the Related Art

In recent years, due to higher integration in semiconductor devices, there has been progress in the miniaturization of structures of elements, such as transistors and the like. More particularly, in a transistor such as a MOS transistor or the like, when the gate length is shortened by miniaturization, electric fields are concentrated at end portions of the gate electrode (gate edges) and the like. As a result, the short-channel effect and suchlike are significant, which leads to effects such as an increase in the off current, a decrease in the breakdown voltage and the like.

Therefore, a lightly doped drain (LDD) configuration, which includes a low density region at a drain end portion adjacent to the channel (to the side of the gate electrode), has been employed as a transistor configuration heretofore. The above-mentioned electric field concentration is ameliorated by this LDD configuration.

However, in a conventional LDD configuration, a range of formation of the low density region is restricted by the height of the gate electrode, the width of a side wall and the like. Moreover, ion implantation for forming the low density region requires energies to be at a level that will not break through the gate electrode. Therefore, in the conventional LDD configuration, the implantation energy tends to be a lower energy in accordance with a reduction in thickness of the gate electrode. Hence, if miniaturization of element structures progresses in the future, it will not be possible to properly form the low density regions below the inside of end portions of a gate electrode in a transistor with the LDD configuration described above. Consequently, it will become more difficult to thoroughly ameliorate electric fields in an element with an LDD configuration.

Accordingly, in Japanese Patent Application Laid-Open (JP-A) No. 8-8430, a MOS transistor fabrication process is proposed. In this process, a protrusion is formed on a semiconductor substrate that is below the gate electrode, impurity ions are implanted in the protrusion from diagonally thereabove, and low density regions are formed in regions at which the source and drain are to be formed below the inside of end portions of the gate electrode.

However, in the configuration of JP-A No. 8-8430, electric fields are concentrated at corners of the protrusion of the semiconductor substrate that are below the end portions of the gate electrode. In addition, if side walls are formed at side surfaces of the gate electrode and gate oxide layer before the low density regions are formed, ranges for formation of the low density regions are limited by the width of the side walls.

### SUMMARY OF THE INVENTION

The present invention provides a transistor, semiconductor device and transistor fabrication process capable of thoroughly ameliorating electric fields in an element.

A first aspect of the present invention is a transistor including: a semiconductor substrate including: a protrusion portion at a surface thereof; incline portions that structure side surface portions of the protrusion portion, and are inclined from a bottom to a top of the protrusion portion; a gate electrode formed on the top of the protrusion portion with a gate insulation film interposed therebelow; side walls formed on the top of the protrusion portion at two side surfaces of the gate electrode and the gate insulation film; low density regions of a source and a drain that are formed in the protrusion portion below the side walls and below the inside of two end portions of the gate electrode; and high-density regions of the source and the drain, that has higher dispersion density than the low density regions, that are formed adjacent to the low density regions, and are formed within the semiconductor substrate at two sides of the protrusion portion.

In the first aspect of the present invention, the low density regions are formed below the inside of the two end portions of the gate electrode. Therefore, the first aspect of the present invention may prevent electric fields being concentrated at the end portions of the gate electrode (gate edges) and the like, since the gate length being shortened due to miniaturization of the transistor.

Furthermore, the first aspect of the present invention includes the incline portions that structure the side surface portions of the protrusion of the semiconductor substrate and that are inclined from the bottom to the top of the protrusion portion, on the top of which the gate electrode is formed with the gate oxide film interposed therebetween. Therefore, corners at the two ends of the top of the protrusion portion are gentler than in related art (than right angles with respect to the semiconductor substrate). Accordingly, the first aspect of the present invention may suppress concentrations of electric fields at the corners of the protrusion portion. Thus, the first aspect of the present invention may provide a transistor capable of thoroughly ameliorating electric fields in the element.

In a second aspect of the present invention, in the above first aspect, the incline portions may include a concave curve.

According to the second aspect of the present invention, there are no corners at the boundaries between the protrusion portion and the semiconductor substrate surface to the two sides of the protrusion portion. Therefore, the second aspect of the present invention may suppress concentrations of electric fields at the boundaries.

A semiconductor device relating to a third aspect of the present invention includes a semiconductor integrated circuit that includes a transistor according to the aspects described above.

Thus, in the third aspect of the present invention, the transistor described above may be employed in a semiconductor device including a semiconductor integrated circuit.

A fourth aspect of the present invention is a transistor fabrication process including: forming a gate electrode on a semiconductor substrate with a gate insulation film interposed therebelow; forming side walls at side surfaces of the gate electrode and gate insulation film; forming an oxide film on an upper face portion of the semiconductor substrate by oxidizing the upper face portion at regions in which a source and a drain are to be formed and is exposed from the side walls; forming a protrusion portion of the semiconductor substrate below the gate electrode and causing the side walls to retreat, by removing the oxide film; forming low density regions at the regions in which the source and drain are to be formed, below the inside of two end portions of the gate electrode, by implanting and thermally dispersing first impurity ions to the protrusion portion from diagonally thereabove; and forming high-density regions having higher dispersion density than the low density regions, at the regions in which the source and drain are to be formed, by implanting and thermally dispersing second impurity ions to two sides of the protrusion portion.

In the fourth aspect of the present invention, the protrusion portion of the semiconductor substrate is formed below the gate electrode and the first impurity ions are implanted into the protrusion from diagonally thereabove. Thus, the fourth aspect of the present invention may make it easier to implant the first impurity ions in step portions between the protrusion portion and the semiconductor substrate to the two sides of the protrusion portion and in the regions at which the source and the drain are to be formed below the inside of the two end portions of the gate electrode.

Furthermore, according to the fourth aspect of the present invention, when the oxide film at the upper face portion of the regions of the semiconductor substrate at which the source and drain are to be formed is removed, a portion of the side walls is also removed and the side walls retreat; that is, the width of the side walls is narrowed. When the width of the side walls is narrowed in this manner, then when the first impurity ions are implanted from diagonally above, an amount of the first impurity ions that is implanted into the protrusion portion increases. Therefore, the fourth aspect of the present invention may form the low density regions more widely in the regions at which the source and drain are to be formed below the inside of the two end portions of the gate electrode. Hence, the fourth aspect of the present invention may thoroughly ameliorate electric fields in the element.

Because the fourth aspect of the present invention employs a step of temporarily oxidizing and removing the upper face portion, in contrast with a case of simply removing an upper face portion that is exposed from side walls at regions at which a source and drain are to be formed in a semiconductor substrate, the two side surface portions of the protrusion are inclined and there are concave curves. Consequently, in the fourth aspect of the present invention, the corners of the two ends of the top of the protrusion portion are gentler than in related art (than right angles with respect to the semiconductor substrate) and there are no corners at the boundaries between the protrusion portion and the semiconductor substrate surface to the two sides of the protrusion portion. Therefore, the fourth aspect of the present invention may suppress concentrations of electric fields at the corners of the protrusion portion and the boundaries, and may provide a transistor capable of thoroughly ameliorating electric fields in the element.

In a fifth aspect of the present invention, in the above fourth aspect, may further include, after forming the gate electrode and before forming the side walls, implanting impurity ions having the same ions as the first impurity irons in the regions at which the source and the drain are to be formed, by using the gate electrode as a mask.

In the fifth aspect of the present invention, ions, the same as the first impurity ions that are implanted when forming the low density regions, are implanted into the regions at which the source and the drain are to be formed in advance, before the side walls are formed. Therefore, the fifth aspect of the present invention may form the low density regions in advance at the regions at which the source and drain are to be formed below the side surfaces that are formed afterward, without being affected by the side surfaces. Hence, in the fifth aspect of the present invention, the low density regions and high density regions may be reliably made adjacent.

According to the aspects described above, the present invention may provide a transistor, semiconductor device and transistor fabrication process that thoroughly ameliorate electric fields in an element.

### BRIEF DESCRIPTION OF THE DRAWINGS

An exemplary embodiment of the present invention will be described in detail based on the following figures, wherein:

FIG. 1 is a diagram illustrating schematic structure of a transistor relating to an exemplary embodiment of the present invention;

FIG. 2A to FIG. 2F are diagrams illustrating a fabrication sequence of a transistor fabrication process relating to the exemplary embodiment of the present invention; and

FIG. 3 is a diagram illustrating schematic structure of a transistor relating to a comparative example.

### DETAILED DESCRIPTION OF THE INVENTION

### (Structure)

First, structure of a transistor relating to an exemplary embodiment of the present invention is described.

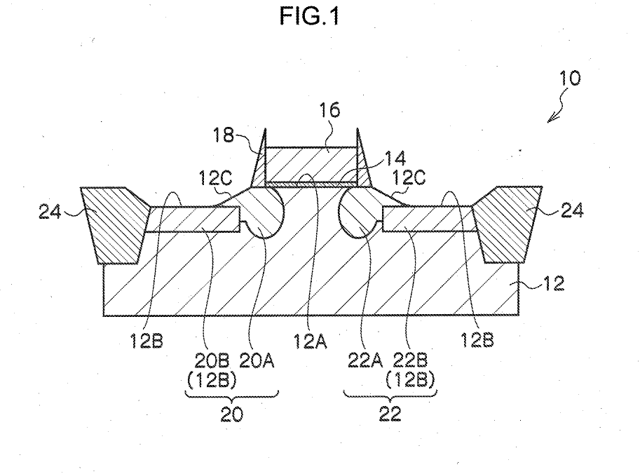

FIG. 1 is a diagram illustrating schematic structure of the transistor relating to the exemplary embodiment of the present invention.

A transistor 10 relating to an exemplary embodiment of the present invention is a metal oxide semiconductor (MOS) transistor, and is provided with a semiconductor substrate 12 formed of, for example, p-type silicon or the like.

A protrusion portion 12A is formed at the semiconductor substrate 12, on the surface thereof, and two side surface portions of the protrusion portion 12A are constituted by incline portions 12C that are inclined from the bottom to the top of the protrusion portion 12A. In all of the attached drawings, each incline portion 12C is inclined in a linear form, however, it is preferable to include a concave curve.

A gate oxide film 14, formed of a silicon oxide film or the like, is formed on the top of the protrusion portion 12A. A gate electrode 16 is formed on the gate oxide film 14.

On the protrusion portion 12A, side walls 18 formed of, for example, a nitride film or the like are formed at side surfaces of the gate electrode 16 and gate oxide film 14.

A source 20 and a drain 22 are formed at the surface of the semiconductor substrate 12, from the two side surface portions of the protrusion portion 12A of the semiconductor substrate 12 (the incline portions 12C) to concave portions 12B that are to the two sides of the protrusion portion 12A.

The source 20 and drain 22 are constituted by low density regions 20A and 22A and high density regions 20B and 22B that have higher diffusion densities of impurities than the low density regions 20A and 22A.

The low density regions 20A and 22A are disposed in the protrusion portion 12A below the side walls 18 and below the inside of the two end portions of the gate electrode 16, sandwiching a channel which is a central portion in the protrusion portion 12A. A dosing amount of the low density regions 20A and 22A is, for example, 1×10¹³ cm⁻² or the like.

The high density regions 20B and 22B are adjacent to end portions of the low density regions 20A and 22A, respectively, and are disposed in the semiconductor substrate 12 at the concave portions 12B to the two sides of the protrusion portion 12A. A dosing amount of the high density regions 20B and 22B is, for example, 1×10¹⁵ cm⁻² or the like.

A shallow trench isolation (STI) 24 is formed to serve as an element isolation region outside of the high density regions 20B and 22B (with the area between the high density regions 20B and 22B to the inner side).

### (Fabrication Process)

Next, a fabrication process of the transistor 10 relating to the exemplary embodiment of the present invention is described.

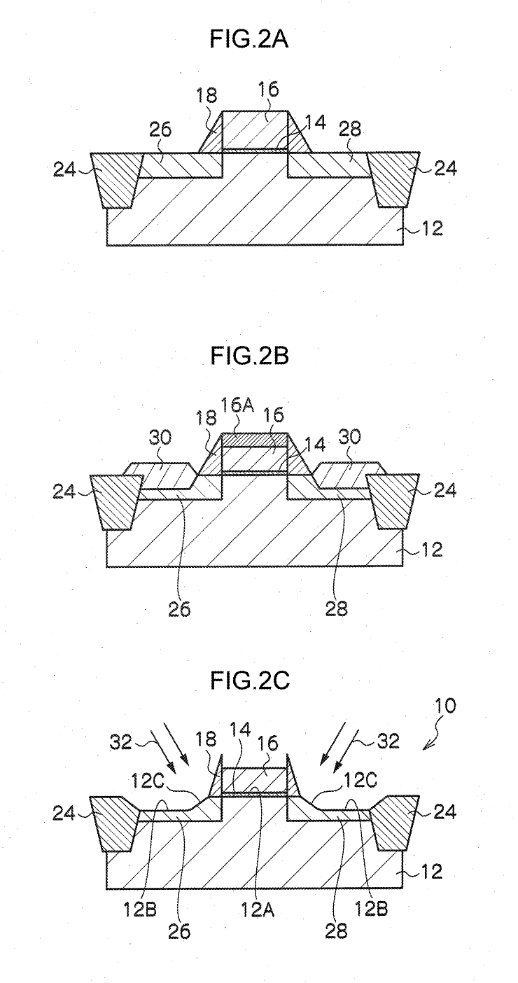

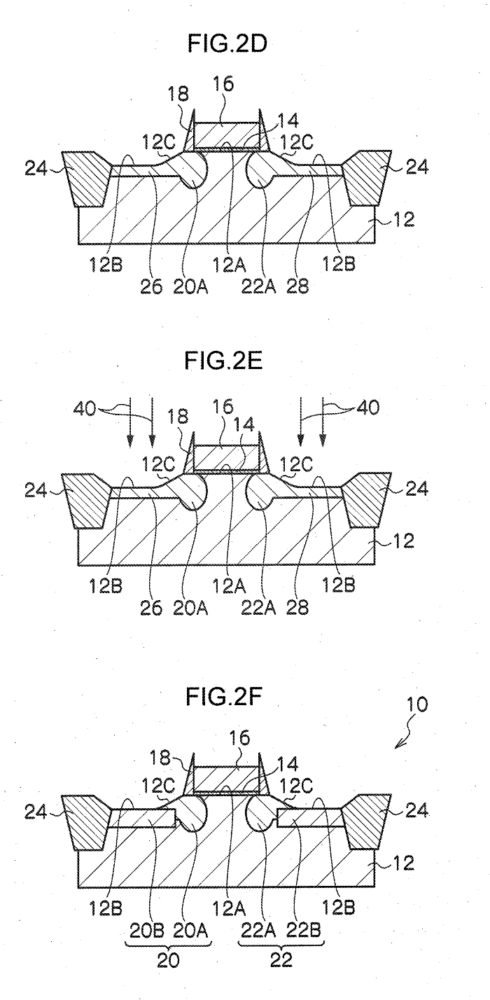

FIG. 2A to FIG. 2F are diagrams illustrating a fabrication sequence of the fabrication process of the transistor 10 relating to the exemplary embodiment of the present invention.

As illustrated in FIG. 2A, the semiconductor substrate 12 formed of silicon or the like is prepared and the STI 24 is formed in the semiconductor substrate 12. After the STI 24 is formed, a p-type impurity that is, for example, boron or the like is implanted into the semiconductor substrate 12. Then, an insulation layer formed of a silicon oxide film or the like and an electrode layer formed of polysilicon or the like, are sequentially layered onto the semiconductor substrate 12. The gate oxide film 14 and the gate electrode 16 are formed on the semiconductor substrate 12 enclosed by the STI 24, by etching with a resist pattern.

Then, using the gate electrode 16 as a mask, impurity ions the same as impurity ions (for example, phosphorus) to be implanted when the low density regions 20A and 22A are formed, which is described below, are implanted in the exposed semiconductor substrate 12. Specifically, the impurity ions are implanted in intended source and drain formation regions 26 and 28 in the semiconductor substrate 12. Then, the side walls 18, formed of a nitride film or the like, are formed on end portions of the intended source and drain formation regions 26 and 28, and on side walls of the gate electrode 16 and gate oxide film 14.

Next, as illustrated in FIG. 2B, using the gate electrode 16 and the side walls 18 as a mask, the semiconductor substrate 12 is oxidized; that is, an upper face portion of the intended source and drain formation regions 26 and 28 of the semiconductor substrate 12 that is exposed from the side walls 18 is oxidized and an oxide layer 30 is formed on this upper face portion. At this time, an oxide film 16A is also formed on an upper face portion of the gate electrode 16.

A method of oxidation is not to be particularly limited, but a method of, for example, putting the semiconductor substrate 12 illustrated in FIG. 2A into an electric furnace and thermally oxidizing the semiconductor substrate 12 while oxygen flows in the electric furnace, or the like, may be used.

Next, as illustrated in FIG. 2C, the oxide layer 30 that has been formed is removed by wet etching, and the protrusion portion 12A is formed at the semiconductor substrate 12 below the gate electrode 16. At the time of wet etching, in addition to the oxide layer 30, a portion of the side walls 18 is removed, and the side walls 18 are retreated (the width of the side walls 18 narrows). The oxide film 16A formed on the upper face portion of the gate electrode 16 is also removed. By the oxide layer 30 being removed, the two side surface portions of the protrusion portion 12A are inclined from the bottom to the top of the protrusion portion 12A. These two side surface portions of the semiconductor substrate 12 are referred to as the incline portions 12C. The incline portions 12C include concave curves.

Then, using the gate electrode 16 as a mask, while a base of the semiconductor substrate 12 is rotated, n-type impurity ions 32 of phosphorus or the like are implanted in the protrusion portion 12A of the semiconductor substrate 12 from diagonally above. This implantation of the n-type impurity ions 32 is carried out at a high energy, at a level so as not to break through the gate electrode 16.

Next, as illustrated in FIG. 2D), the implanted n-type impurity ions 32 are thermally dispersed, the intended source and drain formation regions 26 and 28 spread, and the low density regions 20A and 22A are formed in the intended source and drain formation regions 26 and 28 that have spread to below the inside of the two end portions of the gate electrode 16.

Next, as illustrated in FIG. 2E, impurity ions 40 are implanted in the semiconductor substrate 12 from an incidence angle of approximately 0° with respect to the semiconductor substrate 12. Specifically, for example, n-type impurity ions 40 of the same type as the impurity ions 32 that were implanted when forming the low density regions 20A and 22A are implanted to the two sides of the protrusion portion 12A. For example, arsenic ions may be mentioned as the n-type impurity ions 40.

Finally, as illustrated in FIG. 2F, the implanted n-type impurity ions 40 are thermally dispersed, and the high density regions 20B and 22B with higher dispersal densities than the above-mentioned low density regions 20A and 22A are formed in the intended source and drain formation regions 26 and 28 at the concave portions 12B to the two sides of the protrusion portion 12A.

The transistor 10 relating to the exemplary embodiment of the present invention as illustrated in FIG. 1 may be provided through the fabrication sequence described above.

### (Effects)

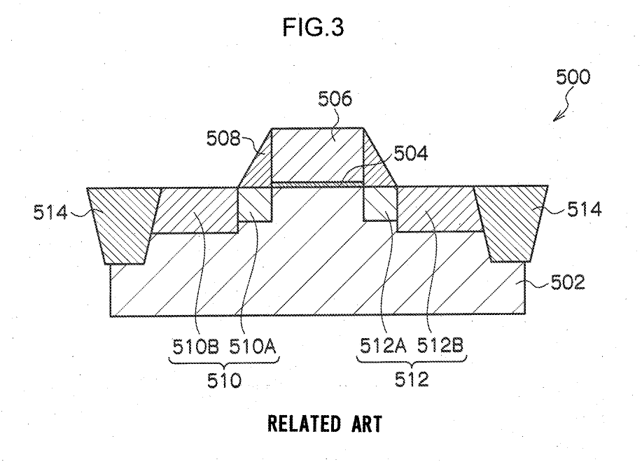

Now, a transistor 500 relating to a comparative example is described. FIG. 3 is a diagram illustrating structure of the transistor 500 relating to the comparative example.

The transistor 500 relating to the comparative example includes a gate electrode 506 that is formed on a p-type semiconductor substrate 502, whose surface is flat, with a gate insulation film 504 interposed therebelow. Side walls 508 are formed on the semiconductor substrate 502 at two side surfaces of the gate electrode 506 and gate insulation film 504. Low density regions 510A and 512A of a source 510 and drain 512 are formed in the semiconductor substrate 502 below the side walls 508. High density regions 510B and 512B of the source 510 and drain 512, with higher dispersion densities than the low density regions 510A and 512A, are formed in the semiconductor substrate 502 to the sides of below the side walls 508, adjacent to the low density regions 510A and 512A. An STI 514 is formed to serve as an element isolation region outside of the high density regions 510B and 512B.

This structure is fabricated by, for example, implanting n-type impurity ions from diagonally above to form the low density regions 510A and 512A before forming the side walls 508 and, after forming the side walls 508, implanting n-type impurity ions in the semiconductor substrate 502 from an incidence angle of approximately 0° with respect to the semiconductor substrate 502.

In contrast, according to the transistor 10 relating to the exemplary embodiment of the present invention, because the low density regions 20A and 22A are formed to further below the inside of the two end portions of the gate electrode 16 than in the comparative example, concentrations of electric fields at end portions of the gate electrode 16 (gate edges) and the like, when the gate length is shortened due to miniaturization of the transistor 10 in association with a higher level of integration of the semiconductor substrate 12, may be prevented.

Moreover, in contrast with the comparative example, because the semiconductor substrate 12 of the present invention includes the incline portions 12C that structure the side surface portions of the protrusion portion 12A of the semiconductor substrate 12 and are inclined from the bottom to the top of the protrusion portion 12A on the top of which the gate electrode 16 is formed with the gate oxide film 14 interposed, corners at the two ends of the top of the protrusion portion 12A are gentler than in the comparative example (than right angles with respect to the semiconductor substrate 12) and concentrations of electric fields at the corners of the protrusion portion 12A are suppressed. Hence, the present invention may provide a transistor capable of thoroughly ameliorating electric fields in the element.

Further, in the present invention, because the incline portions 12C have concave curves, there are no corners at the boundaries between the protrusion portion 12A and the surface of the semiconductor substrate 12 to the two sides of the protrusion portion 12A, and concentrations of electric fields at the boundaries may be suppressed.

According to the process of fabrication of the transistor 10 relating to the exemplary embodiment of the present invention, the protrusion portion 12A of the semiconductor substrate 12 is formed below the gate electrode 16 and the first impurity ions 32 are implanted from diagonally above into the protrusion portion 12A. Therefore, in the present invention, the first impurity ions 32 may be implanted in step portions between the protrusion portion 12A and the semiconductor substrate 12 to the two sides of the protrusion portion 12A and in the intended source and drain formation regions 26 and 28 below the inside of the two end portions of the gate electrode 16 more easily than in the comparative example.

Furthermore, when the oxide layer 30 at the upper face portion of the intended source and drain formation regions 26 and 28 of the semiconductor substrate 12 is removed, a portion of the side walls 18 is removed and the side walls 18 retreat, which is to say the width of the side walls 18 is narrowed. Because the width of the side walls 18 decreases in this manner, when the first impurity ions 32 are implanted from diagonally above, the amount of the impurity ions 32 implanted in the protrusion portion 12A increases. Therefore, in the present invention, the low density regions 20A and 22A may be widely formed in the intended source and drain formation regions 26 and 28 below the inside of the two end portions of the gate electrode 16, and electric fields in the element may be thoroughly ameliorated.

Further, in the present invention, since a step of temporarily oxidizing and then removing the upper face portion is employed, in contrast with a case of removing an upper face portion of the intended source and drain formation regions 26 and 28 in the semiconductor substrate 12 that is exposed from the side walls 18, the two side surface portions of the protrusion portion 12A are inclined and feature concave curves. Consequently, the corners of the two end portions of the top of the protrusion portion 12A are gentler than in the comparative example (than right angles with respect to the semiconductor substrate) and there are no corners at the boundaries between the protrusion portion 12A and the surface of the semiconductor substrate 12 to the two sides of the protrusion portion 12A. Thus, concentrations of electric fields at the corners of the protrusion portion 12A and the boundaries may be suppressed. Hence, the transistor 10 that is capable of thoroughly ameliorating electric fields in the element may be provided.

Further, before the side walls 18 are formed, the impurity ions that are the same as the impurity ions 32 to be implanted when the low density regions 20A and 22A are being formed are implanted in the intended source and drain formation regions 26 and 28 in advance. Therefore, the low density regions may be formed in advance at the intended source and drain formation regions 26 and 28 below the side walls 18 that are formed thereafter, without being affected by the side walls 18, and the low density regions 20A and 22A and the high density regions 20B and 22B that are formed thereafter may be reliably made adjacent.

### Variant Examples

The present invention is not to be limited to the exemplary embodiment described above; numerous alterations, modifications and improvements may be possible.

For example, in the fabrication process of the transistor 10 relating to the exemplary embodiment, a case that includes, after forming the gate electrode 16 and before forming the side wall 18, implanting ions the same as the impurity ions 32 to be implanted when forming the low density regions 20A and 22A into the intended source and drain formation regions 26 and 28, using the gate electrode 16 as a mask, has been described. However, this step may be omitted.

The transistor 10 relating to the exemplary embodiment is particularly useful for application to semiconductor devices with the aim of increasing integration of semiconductor integrated circuits.

The purpose of the STI 24 is to isolate the element when the transistor 10 is employed in a semiconductor device, and therefore the STI 24 is not an essential structure for the present invention.

A case in which the transistor 10 relating to the exemplary embodiment is a p-channel transistor, has been described. However, the transistor may be an n-channel transistor. Furthermore, a case in which the transistor 10 is a MOS transistor, has been described. However, the present invention may also be applied to transistors constituted with other materials, structures and the like.

What is claimed is:

1. A transistor comprising:
a semiconductor substrate including a protrusion portion at a surface thereof;
incline portions that structure side surface portions of the protrusion portion, and are inclined from a bottom to a top of the protrusion portion;
a gate electrode formed on the top of the protrusion portion with a gate insulation film interposed therebelow;
side walls formed on the top of the protrusion portion at two side surfaces of the gate electrode and the gate insulation film;
low density regions of a source and a drain that are formed in the protrusion portion below the side walls and below the inside of two end portions of the gate electrode; and
high-density regions of the source and the drain, that has higher dispersion density than the low density regions, that are formed adjacent to the low density regions, and are formed within the semiconductor substrate at two sides of the protrusion portion.

2. The transistor according to claim 1, wherein the incline portions include a concave curve.

3. A semiconductor device comprising a semiconductor integrated circuit that includes the transistor according to claim 1.

4. A transistor fabrication process comprising:
forming a gate electrode on a semiconductor substrate with a gate insulation film interposed therebelow;
forming side walls at side surfaces of the gate electrode and gate insulation film;
forming an oxide film on an upper face portion of the semiconductor substrate by oxidizing the upper face portion at regions in which a source and a drain are to be formed and is exposed from the side walls;
forming a protrusion portion of the semiconductor substrate below the gate electrode and causing the side walls to retreat, by removing the oxide film;
forming low density regions at the regions in which the source and drain are to be formed, below the inside of two end portions of the gate electrode, by implanting and thermally dispersing first impurity ions to the protrusion portion from diagonally thereabove; and
forming high-density regions having higher dispersion density than the low density regions, at the regions in which the source and drain are to be formed, by implanting and thermally dispersing second impurity ions to two sides of the protrusion portion.

5. The transistor fabrication process according to claim 4, further comprising, after forming the gate electrode and before forming the side walls, implanting impurity ions having the same ions as the first impurity irons in the regions at which the source and the drain are to be formed, by using the gate electrode as a mask.
